(19) United States
(12) Patent Application Publication
(10) Pub. No.: US 2017/0213775 A1
(43) Pub. Date: Jul. 27, 2017

(54) SEMICONDUCTOR DEVICE

(71) Applicant: SII Semiconductor Corporation, Chiba-shi (JP)

(72) Inventor: Kiyoaki KADOI, Chiba-shi (JP)

(21) Appl. No.: 15/412,445

(22) Filed: Jan. 23, 2017

(30) Foreign Application Priority Data
Jan. 26, 2016 (JP) 2016-012514

(51) Int. Cl. H01L 21/66; H01L 23/544

(52) U.S. Cl. CPC H01L 22/34; H01L 23/544; H01L 2223/54433

(57) ABSTRACT

Provided is a semiconductor device in which an internal pressure change in a cavity structure can be inspected. A semiconductor device (1), which is formed of a cavity-type package having a space in an inner part thereof, includes a pressure gauge (2), which enables inspection of a state of an internal space, and which is arranged on a surface of the semiconductor device (1). The pressure gauge (2) is formed of a plurality of straight lines intersecting each other at right angles, and whether there is an internal pressure change or not can be checked through measurement of a change in dimension between intersections.

### BACKGROUND OF THE INVENTION

1. Field of the Invention

The present invention relates to a semiconductor device having a cavity structure, inside which a semiconductor element is mounted.

2. Description of the Related Art

FIG. 11 is a sectional view of a related-art semiconductor device 11 having a cavity structure. In the related-art semiconductor device 11 having the cavity structure, a semiconductor element 12, having a desired electrical circuit formed on its surface, is arranged on an island 16, which is a part of a lead frame. Further, the semiconductor element 12 is electrically connected to external terminals 14 through gold wires 13. A cap material 15, made of metal, is arranged on the lead frame so as to cover the semiconductor element 12 and the gold wires 13.

When an internal space of a package as described above is evacuated, for example, a method of encapsulating a semiconductor device with the cap material 15 in a vacuum chamber is used. And when an internal space of the package is pressurized, a method of encapsulating a semiconductor device with the cap material 15 in a pressurizing chamber is used. Thus the degree of vacuum, the pressurized state, or the like of the internal space of the semiconductor device cannot be known after encapsulation and completion. A change in state of the internal space is rarely noticed. For example, the change in the state of the internal space is discovered for the first time after the semiconductor device loses its original function or performance due to the change of the internal space from a vacuum state to an atmospheric-pressure state. As a result, actions for handling faults in the semiconductor device are delayed.

In a case of the semiconductor device in which the internal space is evacuated as described above, outgas, which is generated during welding, deteriorates the degree of vacuum. In particular, in a high-vacuum semiconductor device, a getter, which is an adsorbing material for adsorbing gas in the inner part of the package, might be arranged inside the package. The outgas from organic materials such as hydrocarbon and the like, however, cannot be adsorbed by the adsorbing material. When the outgas is further generated, metal of the cap material and the lead frame also absorbs the outgas. Thus, as time proceeds, the absorbed outgas is released to the internal space again from the metal causing deterioration to the degree of vacuum.

Further, when the cap material is an organic material or the like in a package whose internal space is pressurized, pressurized gas components permeates inside the organic material to thereby cause a decrease in pressure as time proceeds. Even if the cap material is made from metal, the result will be the same if an adhesive is used.

In other words, when the internal space is depressurized or pressurized, the pressure of the internal space changes in both cases as time proceeds. However, in a cavity-type semiconductor device having the internal space, there is no method of detecting those changes, and thus the state of the internal space cannot be grasped.

### SUMMARY OF THE INVENTION

The present invention has been made in view of the above-mentioned problem, and provides a cavity structure package in which a change in internal pressure can be easily checked.

According to one embodiment of the present invention, the following measures are taken in order to solve the above-mentioned problem.

First, there is provided a semiconductor device having a semiconductor element mounted in an inner part of a cavity structure, in which a pressure gauge for measuring a geometric deformation of the cavity structure due to a change in the internal pressure is arranged on a surface of the semiconductor device.

Further, in the semiconductor device, the pressure gauge includes a plurality of straight lines or curved lines that intersect each other at right angles.

Further, in the semiconductor device, the pressure gauge is arranged on an upper surface or side surface of the semiconductor device.

Further, in the semiconductor device, a first surface is thin compared to other surfaces.

In addition, in the semiconductor device, the pressure gauge includes a first pressure gauge and a second pressure gauge.

As described above, in the cavity-type semiconductor device having the internal space, by arranging the pressure gauge on the surface of the semiconductor device and by inspecting the pressure gauge, the state of the internal space can be known in a nondestructive way.

### BRIEF DESCRIPTION OF THE DRAWINGS

FIG. 1 is a perspective view of a semiconductor device according to a first embodiment of the present invention.

FIG. 2 is a top view of the semiconductor device according to the first embodiment of the present invention.

FIG. 3 is a perspective view of the semiconductor device according to the first embodiment of the present invention.

FIG. 4 is a sectional view of the semiconductor device according to the first embodiment of the present invention.

FIG. 5 is a top view of a semiconductor device according to a second embodiment of the present invention.

FIG. 6 is a perspective view of a semiconductor device according to a third embodiment of the present invention.

FIG. 7 is a sectional view of a semiconductor device according to a fourth embodiment of the present invention.

FIG. 8 is a sectional view of a semiconductor device according to a fifth embodiment of the present invention.

FIG. 9 is a top view of a semiconductor device according to a sixth embodiment of the present invention.

FIG. 10 is a top view of a semiconductor device according to a seventh embodiment of the present invention.

FIG. 11 is a sectional view of a related-art semiconductor device.

### DETAILED DESCRIPTION OF THE INVENTION

Now, modes for carrying out the present invention are described by way of embodiments with reference to the drawings.

### First Embodiment

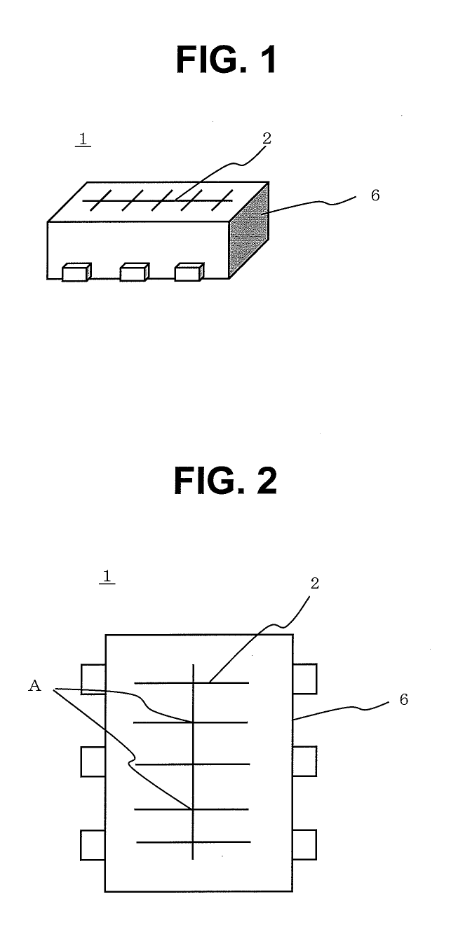

FIG. 1 is a perspective view of a semiconductor device according to a first embodiment of the present invention.

The semiconductor device 1 is formed of a package 6, which is a cavity-type package having a space in an inner part thereof. The package 6 is comprised of an elastically deformable material such as metal, ceramic and resin that can undergo some degree of elastic deformation without rupturing. The semiconductor device 1 includes a pressure gauge 2, which enables inspection of a state of an internal space, on a surface of the package 6. The pressure gauge 2 is formed of a plurality of straight lines that intersect each other at right angles, and has a double-edged comb shape in FIG. 1.

FIG. 2 is a top view of the semiconductor device 1 provided with the pressure gauge illustrated in FIG. 1. There are arranged one long straight line and a plurality of short straight lines. The one long straight line is arranged in a first direction parallel to a first side of the package 6. The first side is in a longitudinal direction of the package 6. The plurality of short straight lines intersect the one long straight line, and are arranged in a second direction parallel to a second side of the package 6 at certain intervals along an upper surface of the package 6. These lines form an effective pressure gauge for observing deformation of the package 6 in the first direction.

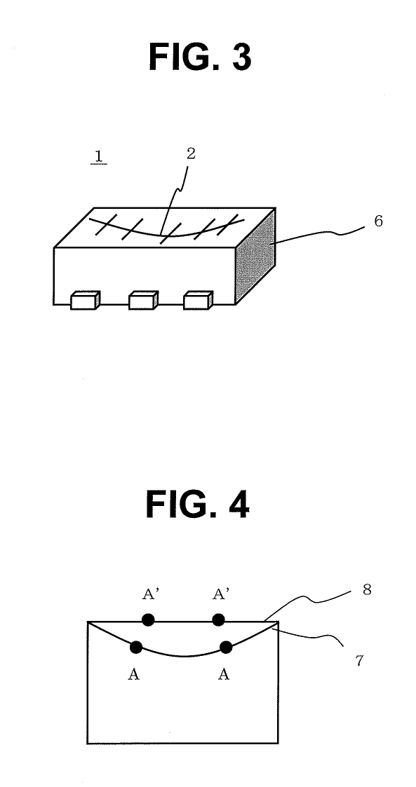

FIG. 3 is a perspective view of the semiconductor device 1 in a case where the internal space is in a vacuum state. In the case of the package having the inner part in the vacuum state, when the pressure gauge 2 as illustrated in FIG. 2 is arranged on the upper surface of the package, a shape deformed (curved) into a concave shape is observed when viewed obliquely as illustrated in FIG. 3. When the degree of vacuum is reduced in such a depressurization-type package, a deformation curvature becomes smaller and the intervals between the plurality of straight lines in the second direction shrink. Through measurement of this shrinkage, it may be checked whether reduction in the vacuum state of the internal space occurs or not. In this way, by using the fact that the intervals between the lines of the pressure gauge 2 change between the vacuum state and a non-vacuum state, it can be easily known whether the degree of vacuum in the inner part of the package has changed or not. Although not shown, deformation in the second direction can be observed by arranging a plurality of straight lines in the first direction. Through laser marking or ink marking, the pressure gauge may be formed after a vacuum package is completed.

FIG. 4 is a sectional view of the package taken along the one long straight line in the first direction of FIG. 2. An upper surface 7 of the package in the vacuum (depressurized) state is illustrated by the curved line that is curved in a concave shape. An upper surface 8 of the package in an atmospheric-pressure state is illustrated by the straight line as a state in which internal pressure and external pressure are balanced. Two intersections A located on the upper surface 7 of the package in the vacuum (depressurized) state move to two intersections A′ of the upper surface 8 of the package illustrated by the straight line when the vacuum (depressurized) state changes to the atmospheric-pressure state. At this time, an interval between the two intersections A′ shrinks and become shorter than an interval between the two intersections A. Using this phenomenon, the change in the degree of vacuum of the inner part of the package may be known. In FIG. 4, the concave shape is formed on the upper surface, but the same applies to a case where the concave shape is formed on a side surface.

The example of arranging the pressure gauge on the package in the depressurized state is described above, but the pressure gauge can also be arranged on a pressurized package. When the internal pressure of the package, which is curved and deformed in a pressurized state, is reduced, the deformation curvature becomes smaller and the intervals between the plurality of straight lines in the second direction shrink. Through measurement of this shrinkage, it may be checked whether reduction in the vacuum state of the internal space occurs or not. In this way, by using the fact that the intervals between the lines of the pressure gauge 2 change between the pressurized state and a non-pressurized state, it can be easily known whether the pressure of the inner part of the package has changed or not.

### Second Embodiment

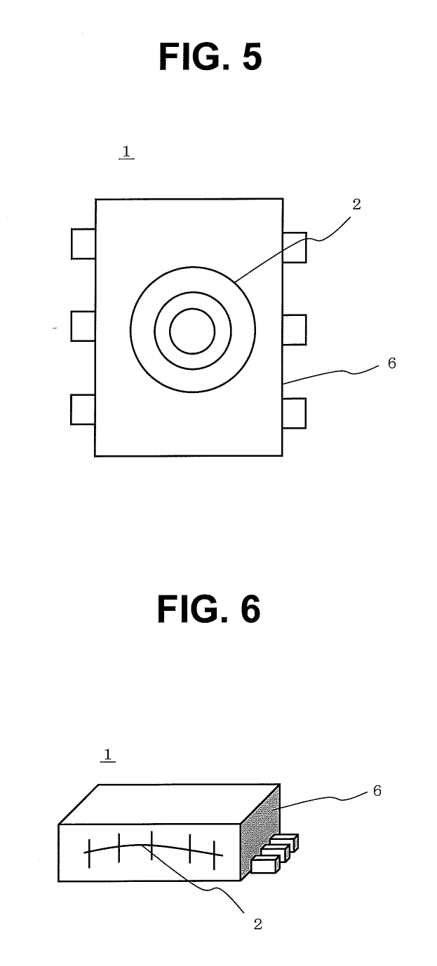

FIG. 5 is a top view of a semiconductor device 1 according to a second embodiment of the present invention. A pressure gauge 2 is arranged on an upper surface of a package 6 of the semiconductor device 1, to thereby enable inspection of the vacuum state of the internal space of the semiconductor device 1 that is mounted on a substrate. The pressure gauge is formed of concentric circles having curved lines, and the vacuum state of the internal space can be known by inspecting gaps between each circle or diameters of the circles. When the package 6 is in the atmospheric-pressure state, the diameter of each circle and the gaps between each circle become smaller as compared to when the package 6 is in the vacuum state.

### Third Embodiment

FIG. 6 is a perspective view of a semiconductor device 1 according to a third embodiment of the present invention. In this embodiment, a pressure gauge is arranged on a side surface of a package 6 of the semiconductor device 1. In some cases, the semiconductor device 1 may have product information marked on an upper surface of the package 6. In that case, the pressure gauge 2 is arranged on the side surface of the package 6. As a result, the vacuum state of the internal space of the semiconductor device 1 can be inspected by inspecting the side surface of the semiconductor device 1 that has been mounted on a substrate. This inspection uses the fact that the concave-shaped deformation formed on an upper surface of the semiconductor device 1 is also formed on the side surface in the same manner. This pressure gauge 2 is formed of straight lines, but a pressure gauge formed of curved lines as described in the second embodiment illustrated in FIG. 5 has the same function. Further, the pressure gauge may be arranged on a plurality of surfaces by combining FIG. 3 and FIG. 6.

### Fourth Embodiment

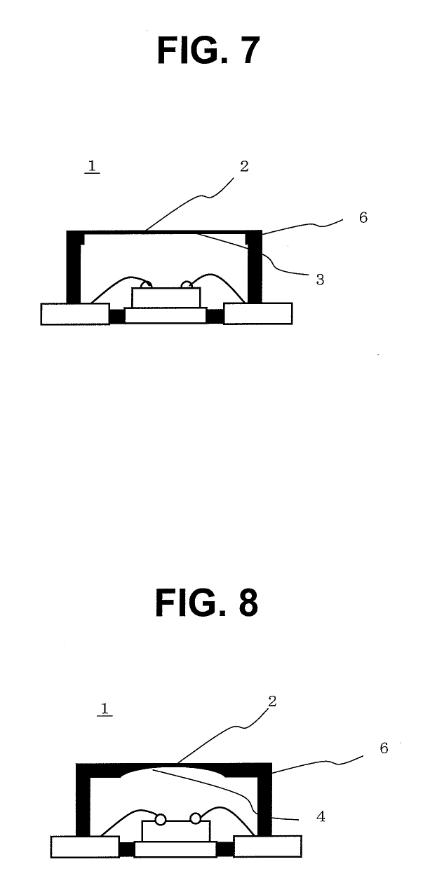

FIG. 7 is a sectional view of a semiconductor device according to a fourth embodiment of the present invention. In the fourth embodiment, a thickness of a member of an upper surface of the semiconductor device 1 that has a pressure gauge 2 is thinner than a portion that does not have the pressure gauge 2 arranged thereon, such that deformation on the surface that has the pressure gauge 2 is larger than deformation on the portion that does not have the pressure gauge 2 arranged thereon, to thereby enhance sensitivity of the pressure gauge 2. In this pressure gauge, the same effect is obtained regardless of whether straight lines or curved lines are used. When the pressure gauge 2 is arranged on a side surface, sensitivity can be enhanced by making a thickness of a member of the side surface thinner than other surfaces.

### Fifth Embodiment

FIG. 8 is a sectional view of a semiconductor device according to a fifth embodiment of the present invention. In the fifth embodiment, by forming a member, which is a part of a surface portion having a pressure gauge 2 arranged thereon, such that the member partially has a portion 4 having a thin member thickness to avoid reduction of member strength of a portion that does not have the pressure gauge 2 arranged thereon. Further, deformation of the portion having the pressure gauge 2 becomes relatively larger than deformation of other portions. As a result, sensitivity of the pressure gauge 2 is enhanced.

### Sixth Embodiment

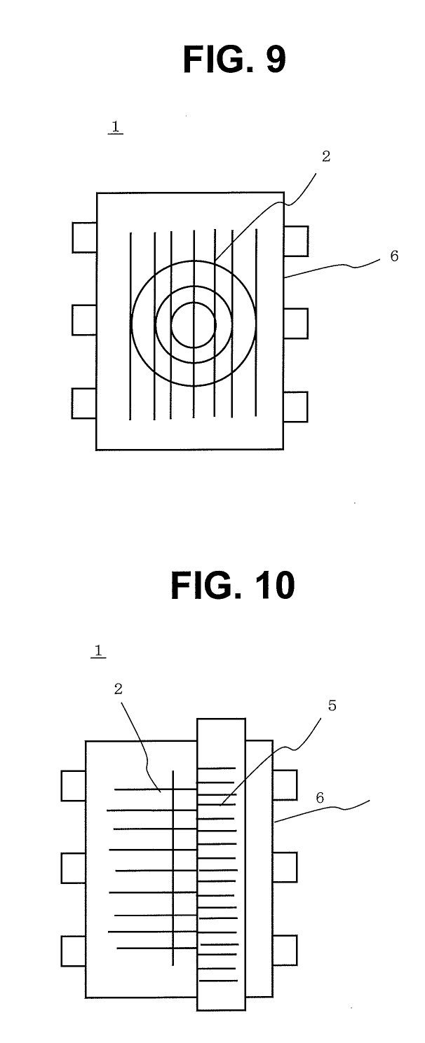

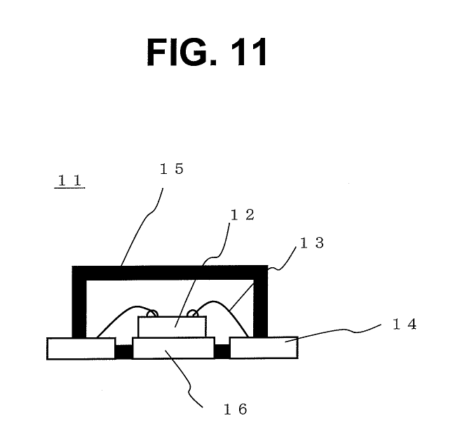

In the present invention, a profile of the semiconductor device 1 having the internal space is deformed, and then deformation amount thereof is easily inspected through the pressure gauge 2. Depending on how the profile of the semiconductor device 1 is deformed, the pressure gauge 2 formed of straight lines may be easier to inspect, or the pressure gauge 2 formed of curved lines may be easier to inspect. Further, a pressure gauge 2 having a shape of both the straight lines and the curved lines is also effective. In FIG. 9, concentric circles and a plurality of straight lines are combined. Further, those pressure gauges 2 are formed on a surface of a semiconductor device 1, and thus the pressure gauges 2 are printed or engraved on a surface of an epoxy-based semiconductor encapsulating resin or a metal material used for a CAN-type semiconductor device.

### Seventh Embodiment

FIG. 10 is a top view of a semiconductor device according to a seventh embodiment of the present invention. In the seventh embodiment, a pressure gauge is formed of a plurality of members. In the seventh embodiment, a second pressure gauge 5 is added other than a first pressure gauge 2 arranged on a surface of the semiconductor device 1. The second pressure gauge 5 is formed at intervals shorter than intervals of the first pressure gauge 2. By arranging the second pressure gauge 5 adjacent to the first pressure gauge 2, the second pressure gauge 5 and the first pressure gauge 2 may be used to have a function of a vernier scale of a caliper. As a result, reading can be performed with a higher accuracy even through visual observation.

What is claimed is:

1. A semiconductor device having a semiconductor element mounted in an inner part of a package having a cavity structure, the semiconductor device comprising, on a surface of the package, a pressure gauge for measuring deformation of a shape of the package due to a change in internal pressure of the cavity structure.

2. A semiconductor device according to claim 1, wherein the pressure gauge comprises a plurality of straight lines that intersect each other at right angles.

3. A semiconductor device according to claim 1, wherein the pressure gauge comprises a plurality of curved lines.

4. A semiconductor device according to claim 1, wherein the pressure gauge is arranged on a first surface of the package.

5. A semiconductor device according to claim 4, wherein the first surface comprises an upper surface of the semiconductor device.

6. A semiconductor device according to claim 4, wherein the first surface comprises a side surface of the semiconductor device.

7. A semiconductor device according to claim 4, wherein the first surface is different from a surface that has identification information of the package marked thereon.

8. A semiconductor device according to claim 4, wherein the first surface is thin compared to other surfaces of the package.

9. A semiconductor device according to claim 4, wherein a part of the first surface is thin compared to other surfaces of the package.

10. A semiconductor device according to claim 1, wherein the pressure gauge comprises a plurality of members, the plurality of members comprising a first pressure gauge and a second pressure gauge.
